(19) United States
(12) Patent Application Publication
(10) Pub. No.: US 2019/0292364 A1
(43) Pub. Date: Sep. 26, 2019

(54) THERMOSETTING RESIN COMPOSITION, PREPREG USING SAME, LAMINATED SHEET, AND PRINTED CIRCUIT BOARD

(71) Applicant: DOOSAN CORPORATION, Seoul (KR)

(72) Inventors: Moo Hyun KIM, Yongin-si (KR); Jeong Don KWON, Yongin-si (KR); Dong Hee JUNG, Yongin-si (KR); Ji Hong SHIN, Yongin-si (KR)

(73) Assignee: DOOSAN CORPORATION, Seoul (KR)

(21) Appl. No.: 16/316,775

(22) PCT Filed: Jun. 30, 2017
(86) PCT No.: PCT/KR2017/006946

§ 371 Date: Jan. 10, 2019

(30) Foreign Application Priority Data
Jul. 12, 2016 (KR) 10-2016-0088207
Jun. 26, 2017 (KR) 10-2017-0080621

(51) Int. Cl. C08L 71/12; C08L 27/18; C08J 5/24; H05K 1/03; H05K 1/02; B32B 15/14; B32B 27/12; B32B 5/02; B32B 15/20

(52) U.S. Cl. CPC C08L 71/12; B32B 2457/08; C08J 5/24; H05K 1/0366; H05K 1/024; B32B 15/14; B32B 27/12; B32B 5/02; B32B 15/20; C08L 2205/14; C08L 2312/00; C08L 2201/02; C08J 2371/12; C08J 2471/12; C08J 2327/18; C08J 2427/18; B32B 2262/101; B32B 2260/021; B32B 2260/046; C08L 27/18

(57) ABSTRACT

The present invention relates to a thermosetting resin composition, and a prepreg, a laminate sheet and a printed circuit board, which use the same. The thermosetting resin composition comprises: (a) a polyphenylene ether having two or more unsaturated substituents, selected from the group consisting of vinyl and allyl groups, at both ends of its molecular chain, or an oligomer thereof; and (b) a polytetrafluoroethylene (PTFE) filler.

### TECHNICAL FIELD

The present invention relates to a novel thermosetting resin composition having improved dielectric constant and dielectric loss, and a prepreg, a laminate sheet, and a printed circuit board using the same.

### BACKGROUND ART

Recently, the signal bands of electronic components and information communication devices, including semiconductor devices, have exhibited a tendency to increase. In this case, the transmission loss of an electric signal is proportional to the dielectric loss tangent and the frequency. Accordingly, as the frequency increases, the transmission loss is increased, a signal is attenuated, and the reliability of signal transmission is lowered. In addition, the transmission loss may be converted into heat, which may cause the problem of heat generation. Therefore, in a high-frequency region, a dielectric material having a very small dielectric loss tangent is required.

In addition, as the demand for higher integration, higher miniaturization, higher performance, and the like of semiconductor devices increases, the densification of integrated and printed circuit boards used for manufacturing semiconductor devices and the narrowing of wiring intervals are required. For this purpose, it is desirable to use a low-dielectric material having low dielectric characteristics, which can increase the transmission speed of signals and reduce transmission loss.

As this material, fluororesin having low dielectric characteristics has been mainly used as a base resin in the prior art.

However, the fluororesin is expensive and has a manufacturing problem in that pressing should necessarily be performed at high temperature and high pressure due to its high melting point. Accordingly, when a prepreg is produced using the fluororesin, problems arise in that cost is increased and molding proccessability is decreased.

### PRIOR ART DOCUMENT

### Patent Document

(Patent Document 1) Korean Patent Application Publication No. 2007-0011493.

### DISCLOSURE

### Technical Problem

In order to overcome the above-described problems, an object of the present invention is to provide a thermosetting resin composition having low dielectric characteristics while having excellent adhesion, heat resistance and curing characteristics.

Another object of the present invention is to provide a prepreg using the thermosetting resin composition, a laminate sheet, and a printed circuit board including the prepreg.

### Technical Solution

In order to accomplish the above objects, the present invention provides a thermosetting resin composition including: (a) a polyphenylene ether having two or more unsaturated substituents, selected from the group consisting of vinyl and allyl groups, at both ends of its molecular chain, or an oligomer thereof; and (b) a polytetrafluoroethylene (PTFE) filler.

In the present invention, the content of the polytetrafluoroethylene (PTFE) filler may range from 10 to 60 parts by weight based on 100 parts by weight of the composition.

In the present invention, the polytetrafluoroethylene (PTFE) filler may have an average particle size ranging from 0.2 to 20 μm and a specific surface area ranging from 1 to 15 m²/g. Preferably, it may have an average particle size ranging from 1 to 10 μm and a specific surface area ranging from 1.5 to 12 m²/g.

The thermosetting resin composition according to the present invention may further include one or more selected from the group consisting of: (c) an inorganic filler; (d) a cross-linkable curing agent; and (e) a flame retardant.

The present invention also provides a prepreg including: a fibrous substrate surface-treated with a vinyl group-containing silane coupling agent; and a resin obtained by impregnating the thermosetting resin composition into the fibrous substrate.

The present invention also provides a laminate sheet including: a metal foil or a polymer film substrate; and a resin layer formed on one or both surfaces of the metal foil or the polymer film substrate through the curing of the thermosetting resin composition.

In the present invention, the laminate sheet may have a dielectric loss (Df) of 0.0025 or less at 1 GHz and a dielectric constant (Dk) of 3.75 or less, as measured in according to IPC TM 650 2.5.5.9.

The present invention provides a printed circuit board including the prepreg.

### Advantageous Effects

The thermosetting resin composition of the present invention has high glass transition temperature (Tg) and excellent heat resistance and proccessability, and exhibits low dielectric characteristics. Therefore, it may be advantageously used for the manufacture of a printed circuit board which is used in various electric and electronic devices, such as mobile communication devices handling signals with a high frequency of 1 GHz or more (in particular, 10 GHz), base station devices therefore, network-related electronic devices, i.e., a server, a router, etc., large-scale computers, etc.

### MODE FOR INVENTION

The present invention will be described below.

The present invention is intended to provide a thermosetting resin composition which may be useful for a printed circuit board, particularly, a multi-layer printed circuit board for high-frequency applications.

The dielectric loss of an electric signal is proportional to the product of the square root of the relative permittivity of a dielectric layer which forms a circuit, the dielectric tangent, and the frequency of the electric signal. Accordingly, the higher the frequency of the electric signal is, the greater the dielectric loss is. Therefore, in order to be used in a dielectric layer of a high-frequency printed circuit board, it is necessary to use a material having a low dielectric constant and a low dielectric loss factor (dielectric loss).

In the conventional art, in order to satisfy a low dielectric constant and low dielectric loss characteristics, fluororesins having low dielectric characteristics were mainly used. However, fluororesins needed to be subjected to high-temperature extrusion molding at 300° C. or higher due to their high melting point, resulting in an increase in production cost and a decrease in molding proccessability.

Accordingly, the present invention is characterized in that the resin component of the thermosetting resin composition is based on a polyphenylene ether resin (hereinafter referred to as “PPE”) having excellent dielectric characteristics and polytetrafluoroethylene (PTFE), i.e., a kind of fluoropolymer, is added thereto as a filler, not as a resin, and is used in combination therewith.

The thermosetting resin composition of the present invention, which includes a combination of the PPE resin and the PTFE filler as described above, may be subjected to a conventional prepreg production process known in the art, e.g., a process that impregnates the thermosetting resin composition with glass fiber, followed by pressing (pressure: 35 kgf/cm², and temperature: 200° C.), instead of a high-temperature extrusion molding process at 300° C. or higher, which should necessarily be performed when conventional fluororesin is used. Accordingly, it can reduce the production cost and increase the ease of processing.

In addition, in the present invention, the PPE resin having low dielectric characteristics and easy proccessability is used as a base component, and the polytetrafluoroethylene (PTFE) having a dielectric constant of about 2.1 is added thereto at a predetermined ratio. Accordingly, the composition can exhibit an excellent low dielectric constant (Dk) and low dielectric loss (Df) characteristics without being influenced by the inherent characteristics of the PPE resin, and at the same time, can exhibit high glass transition temperature (Tg) and excellent heat resistance (T-288).

1. Thermosetting Resin Composition

The present invention provides a thermosetting resin composition which may be useful for a printed circuit board, particularly a multi-layer printed circuit board for high-frequency applications. The thermosetting resin composition will be described in detail below.

The thermosetting resin composition is a non-epoxy-based thermosetting resin composition, and includes: a polyphenylene ether having two or more substituents, selected from the group consisting of vinyl and allyl groups, at both ends of its molecular chain, or an oligomer thereof; and (b) a polytetrafluoroethylene filler which is a fluorine-based filler. It may optionally further include: (c) an inorganic filler; (d) a cross-linkable curing agent; (e) a flame retardant; or a mixture of one or more thereof.

(a) Polyphenylene Ether

The polyphenylene ether (PPE) or an oligomer thereof, which is included in the thermosetting resin composition of the present invention, may have two or more unsaturated double bond moieties at both ends of its molecular chain. As the unsaturated double bond moiety, a conventional moiety known in the art may be used without limitation. As one example, the moiety may be a vinyl group, an allyl group, or both.

When the physical properties of the thermosetting resin composition of the present invention are taken into account, the polyphenylene ether is preferably a compound represented by Formula 1 below. The reason for this is that the compound represented by Formula 1 below has a high glass transition temperature and a low thermal expansion coefficient due to two or more vinyl groups introduced at both ends and exhibits excellent moisture resistance and dielectric characteristics due to a reduced content of hydroxyl groups (OH).

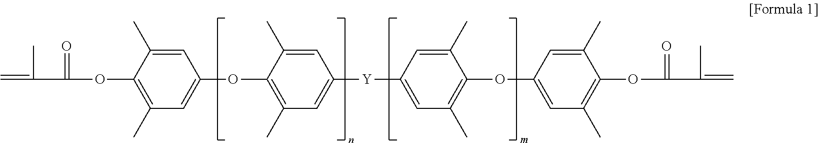

wherein Y is selected from the group consisting of bisphenol A-type resin, bisphenol F-type resin, bisphenol S-type resin, naphthalene-type resin, anthracene resin, biphenyl-type resin, tetramethyl biphenyl-type resin, phenol novolac-type resin, cresol novolac-type resin, bisphenol A novolac-type resin, and bisphenol S novolac-type resin, and m and n are each an integer ranging from 3 to 20.

Although the polyphenylene ether or an oligomer thereof of the present invention is defined as having two or more vinyl and/or allyl groups at both ends of its molecular chain, those having unsaturated double bond moieties known in the art, in addition to the vinyl and/or allyl groups, may also fall within the scope of the present invention.

Meanwhile, polyphenylene ether essentially has a high melting point, and thus a resin composition including the same has a high melt viscosity that makes it difficult to produce a multilayer laminated sheet. Accordingly, in the present invention, it is preferable to use a polyphenylene ether modified to have a low molecular weight by a redistribution reaction, rather than using a conventional high-molecular-weight polyphenylene ether without change. In the present invention, as a catalyst for the redistribution reaction of polyphenylene ether, specific bisphenol derivatives having an increased alkyl group content and aromatic content may be used, thereby increasing the low dielectric characteristics of the thermosetting resin composition.

In other words, in the conventional art, a compound, such as a phenol derivative or bisphenol A, was used in order to modify a high-molecular-weight polyphenylene ether into a low-molecular-weight polyphenylene ether, in which case the molecular structure could be rotated, thereby limiting the improvement of the dielectric characteristics. Specifically, in the conventional art, a high-molecular-weight polyphenylene ether was modified into a low-molecular-weight polyphenylene ether, which has alcohol groups at both ends, by use of polyphenol and a radical initiator as catalysts. However, lowering the dielectric constant and the dielectric loss was limited due to the structural characteristics of the polyphenol bisphenol A used in the redistribution reaction and the high polarity of the alcohol groups introduced at both ends.

However, according to the present invention, as polyphenol for use in the redistribution reaction, specific bisphenol derivatives having an increased alkyl group content and aromatic content are used to perform the redistribution reaction, thereby obtaining a low-molecular-weight polyphenylene ether in which vinyl and/or allyl groups with low polarity in place of alcohol groups with high polarity are introduced at both ends. This low-molecular-weight polyphenylene ether has a lower molecular weight and a higher alkyl group content than conventional polyphenylene ether derivatives. Accordingly, when it is included in a thermosetting resin composition, there may be provided the thermosetting resin composition which has excellent compatibility with conventional epoxy resin or the like and which also has improved workability and dielectric characteristics.

The above-described specific bisphenol derivatives having an increased alkyl group content and aromatic content are not particularly limited, but are preferably, e.g., bisphenol-based compounds, excluding bisphenol A [BPA, 2,2-bis(4-hydroxyphenyl)propane].

In the present invention, specific examples of the specific bisphenol derivatives may include bisphenol AP (1,1-bis(4-hydroxyphenyl)-1-phenyl-ethane), bisphenol AF (2,2-bis(4-hydroxyphenyl)hexafluoropropane), bisphenol B (2,2-bis(4-hydroxyphenyl)butane), bisphenol BP (bis-(4-hydroxyphenyl)diphenylmethane), bisphenol C (2,2-bis(3-methyl-4-hydroxyphenyl)propane), bisphenol C (bis(4-hydroxyphenyl)-2,2-dichlorethylene), bisphenol G (2,2-bis(4-hydroxy-3-isopropyl-phenyl)propane), bisphenol M (1,3-bis(2-(4-hydroxyphenyl)-2-propyl)benzene), bisphenol P (bis(4-hydroxyphenyl)sulfone), bisphenol PH (5,5′-(1-methylethyliden)-bis[1,1′-(bisphenyl)-2-ol]propane), bisphenol TMC (1,1-bis(4-hydroyphenyl)-3,3,5-trimethyl-cyclohexane), or bisphenol Z (1,1-bis(4-hydroxyphenyl)-cyclohexane). These components may be used alone or as a mixture of two or more. In the present invention, when the redistribution reaction is performed using the above-described specific bisphenol derivative, Y in Formula 1 above may be a divalent group derived from the above-described specific bisphenol derivative.

This polyphenylene ether of the present invention may be a low-molecular-weight polyphenylene ether obtained by modifying a high-molecular-weight polyphenylene ether, which has a number-average molecular weight (Mn) ranging from 10,000 to 30,000, through the redistribution reaction in the presence of the above-described bisphenol derivatives (excluding bisphenol A). It may have a number-average molecular weight (Mn) of 1,000 to 10,000, preferably 1,000 to 5,000, more preferably 1,000 to 3,000.

Furthermore, the polyphenylene ether of the present invention preferably has a molecular weight distribution (Mw/Mn) of 3 or less, more preferably 1.5 to 2.5.

When the physical properties of the thermosetting resin composition are taken into account, the content of the polyphenylene ether or an oligomer thereof, of the present invention, is not particularly limited, but may range from 20 to 45 wt %, preferably from 25 to 40 wt %, based on 100 wt % of the thermosetting resin composition.

(b) Polytetrafluoroethylene (PTFE) Filler

The polytetrafluoroethylene (PTFE) filler which is included in the thermosetting resin composition of the present invention functions to lower the dielectric characteristics of the thermosetting resin composition.

This PTFE filler is a fluorine-based material having a dielectric constant of about 2.1, and can thus exhibit low dielectric characteristics. In addition, since it is added as a filler, it can provide the ease of a dielectric layer formation process without requiring a high-temperature press molding process.

Meanwhile, as the polytetrafluoroethylene (PTFE) is more uniformly distributed in the thermosetting resin composition, the dielectric characteristics of the thermosetting resin composition can be improved, and it is also suitable for a glass impregnation process and press molding process for manufacturing a CCL. Accordingly, in the present invention, it is preferable to control the average particle size, specific surface area and/or content of the polytetrafluoroethylene filler in specific ranges.

Specifically, the polytetrafluoroethylene filler of the present invention may have an average particle size ranging from 0.2 to 20 μm and a specific surface area ranging from 1 to 15 m²/g. Preferably, it may have an average particle size ranging from 1 to 10 μm and a specific surface area ranging from 1.5 to 12 m²/g. When it has the above-described particle size and specific surface area, it is uniformly distributed in the thermosetting resin composition without agglomeration, indicating that it is suitable for forming a prepreg for a printed circuit board.

In the present invention, as the polytetrafluoroethylene (PTFE) filler, a PTFE filler having a particular particle size and a specific surface area may be used alone, or two or more PTFE fillers having different particle sizes and specific surface areas may be used.

According to one preferred example of the present invention, as the polytetrafluoroethylene (PTFE) fillers, the following fillers may be used alone or in combination: (i) a first polytetrafluoroethylene filler having an average particle size of 1 to 9 μm and a specific surface area of 1.5 to 3 m²/g; (ii) a second polytetrafluoroethylene filler having an average particle size of 1 to 10 μm and a specific surface area of 5 to 10 m²/g; and (iii) a third polytetrafluoroethylene filler having an average particle size of 1 to 5 μm and a specific surface area of 8 to 11 m²/g.

The content of this polytetrafluoroethylene filler of the present invention is not particularly limited, and may preferably be, e.g., in the range of 10 to 60 wt % based on 100 wt % of the thermosetting resin composition. When the physical properties of the thermosetting resin composition of the present invention are taken into account, the content of the polytetrafluoroethylene filler may preferably be in the range of 10 to 57 wt %, more preferably 10 to 50 wt %, based on 100 wt % of the resin composition.

(c) Inorganic Filler

The thermosetting resin composition of the present invention may further include an inorganic filler in order to increase the mechanical strength and to minimize the difference in thermal expansion coefficient between a resin layer formed using the composition and another layer adjacent thereto.

This inorganic filler is not particularly limited as long as it is known in the art. For example, it is preferably an inorganic filler surface-treated with a vinyl group-containing silane coupling agent. The reason for this is that the inorganic filler surface-treated with a vinyl group-containing silane coupling agent has excellent compatibility with the above-described polyphenylene ether having vinyl and/or allyl groups, and, thus, can significantly increase and improve the dielectric characteristics, heat resistance, proccessability and the like of the thermosetting resin composition according to the present invention.

An inorganic filler which is used for surface treatment with the vinyl group-containing silane coupling agent is not particularly limited, and examples thereof may include silica, such as natural silica, fused silica, amorphous silica, crystalline silica or the like, boehmite, alumina, talc, spherical glass, calcium carbonate, magnesium carbonate, magnesia, clay, calcium silicate, titanium oxide, antimony oxide, glass fiber, aluminum borate, barium titanate, strontium titanate, calcium titanate, magnesium titanate, bismuth titanate, barium zirconate, calcium zirconate, boron nitride, silicon nitride, mica, or the like. These components may be used alone or as a mixture of two or more.

In addition, the particle size of the inorganic filler is not particularly limited, but the average particle size thereof preferably ranges from about 0.5 to 5 μm when its dispersion is taken into account.

A method for treating the surface of the inorganic filler with the vinyl group-containing silane coupling agent is not particularly limited, and may include a method including adding the inorganic filler to a solution containing the vinyl group-containing silane coupling agent, followed by drying.

The content of this inorganic filler of the present invention is not particularly limited, and may preferably be, e.g., in the range of 0 to 30 wt % based on 100 wt % of the thermosetting resin composition. When the physical properties of the thermosetting resin composition of the present invention are taken into account, the content of the inorganic filler ranges preferably from 5 to 30 wt %, more preferably from 10 to 30 wt %, based on 100 wt % of the thermosetting resin composition.

(d) Cross-Linkable Curing Agent

The thermosetting resin composition of the present invention may further include a cross-linkable curing agent in order to improve the bond structure of the polyphenylene ether.

The cross-linkable curing agent three-dimensionally crosslinks the polyphenylene ether to form a network structure, and can thus improve the heat resistance of the thermosetting resin composition of the present invention, which includes the polyphenylene ether modified to have a low molecular weight. In addition, it can increase the flowability of the thermosetting resin composition of the present invention, and can also increase the strength of peeling from another substrate (e.g., a copper foil).

The cross-linkable curing agent which may be used in the present invention is not particularly limited, and, for example, a curing agent containing three or more functional groups is preferably used.

The curing agent containing three or more functional groups is not particularly limited, and specific examples thereof may include triallyl isocyanurate (TAIC), 1,2,4-trivinyl cyclohexane (TVCH), or the like. These components may be used alone or as a mixture of two or more.

In this case, as the triallyl isocyanurate (TAIC), a compound represented by Formula 2 below is preferably used.

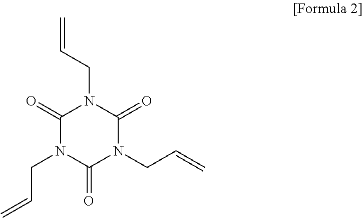 [SMILES: C=CCn1c(=O)n(CC=C)c(=O)n(CC=C)c1=O]

When the physical properties of the thermosetting resin composition are taken into account, the content of this cross-linkable curing agent is not particularly limited, but may range from 5 to 20 wt %, preferably from 10 to 20 wt %, based on 100 wt % of the thermosetting resin composition.

(e) Flame Retardant

The thermosetting resin composition of the present invention may further include a flame retardant in order to increase the flame retardancy.

The flame retardant is not particularly limited as long as it is known in the art, and examples thereof include halogen flame retardants containing bromine or chlorine; phosphorus-based flame retardants, such as triphenyl phosphate, tricresyl phosphate, tris(dichloropropyl) phosphate, phosphazene, or the like; and inorganic flame retardants, such as aluminum hydroxide, magnesium hydroxide or the like.

In the present invention, a brominated flame retardant is preferably used, which is not reactive with the polyphenylene ether and does not deteriorate heat resistance and dielectric characteristics. Specifically, in the present invention, bromophthalimide, a bromophenyl addition-type brominated flame retardant, tetrabromo bisphenol A allyl ether in the allyl terminated form, or a flame-retardant curing agent in the form of divinylphenol, may be used, in which case curing agent characteristics and flame retardant characteristics can be improved simultaneously. In addition, a brominated organic compound may also be used. Examples of this brominated organic compound include decabromodiphenyl ethane, 4,4-dibromobiphenyl, ethylene bis-tetrabromo phthalimide, or the like.

When the physical properties of the thermosetting resin composition are taken into account, the content of the flame retardant agent of the present invention is not particularly limited, but may range from 1 to 15 wt %, preferably from 5 to 10 wt %, based on 100 wt % of the thermosetting resin composition.

According to one preferred example of the present invention, the thermosetting resin composition may include, based on 100 wt % of the composition, 20 to 45 wt % of the polyphenylene ether or an oligomer thereof, 10 to 60 wt % of the polytetrafluoroethylene, 0 to 30 wt % of the inorganic filler, 5 to 20 wt % of the cross-linkable curing agent, and 1 to 15 wt % of the flame retardant.

Meanwhile, the thermosetting resin composition of the present invention may optionally further include a reaction initiator, a curing accelerator, or the like.

The reaction initiator can accelerate the curing reaction of the polyphenylene ether with the cross-linkable curing agent and increase the heat resistance of thermosetting resin composition. Non-limiting examples of this reaction initiator include α,α′-bis(t-butylperoxy-m-isopropyl)benzene, 2,5-dimethyl-2,5-di(t-butylperoxy)-3-hexyne, benzoyl peroxide, 3,3′,5,5′-tetramethyl-1,4-diphenoxyquinone, chloranil, 2,4,6-tri-t-butylphenol, t-butylperoxyisopropyl monocarbonate, azobisisobutyronitrile, or the like. Additionally, a metal carboxylate salt may further be used.

The curing accelerator is not particularly limited, and examples thereof include organic metal salts or organic metal complexes containing one or more metals selected from the group consisting of iron, copper, zinc, cobalt, lead, nickel, manganese, and tin.

Specific examples of the organic metal salts or organic metal complexes may include iron naphthenate, copper naphthenate, zinc naphthenate, cobalt naphthenate, nickel naphthenate, manganese naphthenate, tin naphthenate, zinc octanoate, zinc octanoate, iron octanoate, copper octanoate, zinc 2-ethylhexanoate, lead acetylacetonate, cobalt acetylacetonate, dibutyltin malate, or the like. These components may be used alone or as a mixture of two or more.

The content of the above-described reaction initiator and curing accelerator may be suitably controlled in a conventional range known in the art. For example, the reaction initiator and/or the curing accelerator may be included in an amount of 0.1 to 10 wt % based on 100 wt % of the thermosetting resin composition.

In addition, the thermosetting resin composition of the present invention may optionally further include: various polymers, such as thermosetting resins other than the above-described thermosetting resin, a thermoplastic resin, and oligomers thereof; solid rubber particles; or additives, such as an UV absorber, an antioxidant, a polymerization initiator, a dye, a pigment, a dispersing agent, a thickener, a leveling agent, and the like, within the range that does not impair the physical properties of the resin composition.

2. Prepreg

The present invention provides a prepreg produced using the above-described thermosetting resin composition. Specifically, the prepreg of the present invention includes: a fibrous substrate surface-treated with a vinyl group-containing silane coupling agent; and a resin obtained by impregnating the above-described thermosetting resin composition into the fibrous substrate. In this case, the thermosetting resin composition may be in the form of a resin varnish dissolved or dispersed in a solvent.

The component included in each of the fibrous substrate and the thermosetting resin composition has vinyl groups. Accordingly, when the thermosetting resin composition is impregnated into the fibrous substrate surface-treated with the vinyl group-containing silane coupling agent, the fibrous substrate and the thermosetting resin composition have excellent compatibility therebetween, and thus there may be provided a material for high-frequency applications, which has improved dielectric characteristics and improved heat resistance and proccessability.

In the present invention, the fibrous substrate is not particularly limited as long as it is one obtained by treating the surface of a fibrous substrate known in the art with the vinyl group-containing silane coupling agent. In this case, the fibrous substrate to be surface-treated may be selected based on the intended use or performance.

Specifically, examples of the fiber substrate may include: inorganic fiber, such as glass fiber, e.g., E-glass, D-glass, S-glass, NE-glass, T-glass, Q-glass or the like; organic fiber, such as polyimide, polyamide, polyester, aromatic polyester, fluorine resin or the like; a mixture of the inorganic fiber and the inorganic mixture; paper, nonwoven fabric, woven fabric, or the like, which is made of the organic fiber and/or the inorganic fiber; roving; and mats composed of chopped strand mat, surfacing mat, or the like. These are surface-treated with the vinyl group-containing silane coupling agent, and may be used alone or as a mixture of two or more. When a reinforced fiber substrate is used in combination, it can enhance the rigidity and dimensional stability of the prepreg.

According to one example of the present invention, the fiber substrate used may be glass fiber, glass paper, glass web, glass cloth, aramid fiber, aramid paper, polyester fiber, carbon fiber, inorganic fiber, organic fiber, or a mixture of two or more thereof.

The thickness of the fibrous substrate is not particularly limited, and preferably ranges about 0.01 to 0.3 mm.

A method of treating the surface of this fibrous substrate with the vinyl group-containing silane coupling agent is not particularly limited. For example, a method which is the same as the method of treating the surface of the inorganic filler with the vinyl group-containing silane coupling agent may be applied.

Meanwhile, the prepreg of the present invention may be produced according to a method known in the art.

Specifically, the prepreg of the present invention refers to a sheet-like material including a resin impregnated in the fibrous substrate, which is obtained by coating or impregnating the thermosetting resin composition onto or into a fibrous substrate surface-treated with a vinyl group-containing silane coupling agent, and then curing the fibrous substrate to B-stage (half-curing state) by heating. In this case, the heating temperature and time of the fibrous substrate impregnated with the thermosetting resin composition are not particularly limited, but the heating temperature preferably ranges from about 20 to 200° C. (particularly from 70 to 170° C.), and the heating time ranges from about 1 to 10 minutes. In addition to this method, the prepreg of the present invention may be produced by a method, such as a solvent method, a hot-melt method, or the like.

The solvent method is a method in which a resin varnish obtained by mixing the thermosetting resin solvent with an organic solvent is impregnated into the fibrous substrate and then dried. In this case, the method of impregnating the resin varnish into the fibrous substrate is not particularly limited, but examples thereof may include a method of immersing the fibrous substrate in the resin varnish, a method of applying the resin varnish to the fibrous substrate by means of various coaters, a method of spraying the resin varnish onto the fibrous substrate, and the like. Among these methods, the method of immersing the fibrous substrate in the resin varnish is preferably used because it can improve the impregnation of the resin varnish into the fibrous substrate.

The organic solvent which is used to prepare the resin varnish is not particularly limited, and may be a conventional organic solvent known in the art. Examples of the organic solvent may include: ketones, such as acetone, methyl ethyl ketone cyclohexanone, and the like; acetic acid esters, such as ethyl acetate, butyl acetate, cellosolve acetate, propylene glycol monomethyl ether acetate, carbitol acetate, and the like; carbitols, such as cellosolve, butyl carbitol and the like; aromatic hydrocarbons, such as toluene, xylene, and the like; and dimethylformamide, dimethylacetamide, N-methylpyrrolidone, tetrahydrofuran, and the like. These organic solvents may be used alone or as a mixture of two or more.

The hot-melt method is a method in which the thermosetting resin composition is coated on release paper which is then laminated on a sheet-like fibrous substrate, or the thermosetting resin composition is coated directly on the sheet-like fibrous substrate by a die coater. In addition, the hot-melt method may also be a method in which an adhesive film composed of the thermosetting resin composition is placed on both surfaces of a sheet-like fibrous substrate, and then continuously laminated by heating and pressing.

This prepreg of the present invention includes a resin formed through the curing of the above-described thermosetting resin composition, and can thus exhibit improved low dielectric characteristics while having excellent adhesion, heat resistance, and curing properties.

3. Laminate Sheet

The present invention provides a laminate sheet produced using the above-described thermosetting resin composition. Specifically, the laminate sheet of the present invention includes: a metal foil or a polymer film substrate; and a resin layer formed on one or both surfaces of the metal foil or the polymer film substrate through the curing of the above-described thermosetting resin composition.

An example of this laminate sheet of the present invention may include a copper foil sheet (or a copper foil laminate) including: a metal foil; and a resin layer formed on one or both surfaces of the metal foil through the curing of the above-described thermosetting resin composition.

The metal foil may be made of a metal or alloy known in the art, and may preferably be a copper foil. Examples of a usable copper foil include CFL (TZA_B, HFZ_B), Mitsui (HSVSP, MLS-G), Nikko (RTCHP), Furukawa, ILSIN, and the like. In addition, the copper foil may be any copper foil produced by a rolling method or an electrolysis method. Furthermore, the copper foil may be subjected to rust-prevention treatment in order to prevent the surface thereof from being oxidized and corroded.

The metal foil may have a surface roughness (Rz) formed on a surface in contact with the resin layer formed through the curing of the thermosetting resin composition of the present invention. In this case, the surface roughness (Rz) is not particularly limited, but preferably ranges from 0.6 to 3.0 μm.

The thickness of this metal foil is not particularly limited, but is preferably 5 μm, more preferably 1 to 3 μm, when the thickness and mechanical properties of the laminate sheet are taken into account.

Meanwhile, a polymer film substrate included in the laminate sheet of the present invention is not particularly limited as long as it is a dielectric film known in the art, and examples thereof include a polyimide film, an epoxy resin film, and the like.

This laminate sheet of the present invention includes a resin layer formed through the curing of the above-described thermosetting resin composition, and can thus exhibit improved low dielectric characteristics while having excellent adhesion, heat resistance and curing properties.

4. Printed Circuit Board

The present invention provides a printed circuit board including the above-described prepreg.

Specifically, the printed circuit board of the present invention includes a laminate sheet formed by overlapping two or more of the aforementioned prepreg, and then heating and pressing the overlapped prepregs under conventional conditions. The laminate sheet functions as a dielectric layer, an adhesive layer, a coverlay layer, or the like in the printed circuit board.

This printed circuit board may be produced according to a method known in the art. Specifically, the printed circuit board may be produced by laminating a copper foil on one or both surfaces of the above-described prepreg, heating and pressing the resulting structure to form a copper foil laminate, forming a through-hole in the copper foil laminate, plating the through-hole, and then etching the copper foil to form a circuit.

This printed circuit board of the present invention is produced using a resin layer formed through the curing of the above-described thermosetting resin composition, and thus has a low dielectric constant and low dielectric loss while having a low coefficient of thermal expansion (CTE), high glass transition temperature (Tg), and excellent heat resistance. Accordingly, the printed circuit board of the present invention may be advantageously used as a printed circuit board which is used in various electric and electronic devices, such as mobile communication devices handling signals with a high frequency of 1 GHz or more, base station devices therefore, network-related electronic devices, i.e., a server, a router, etc., large-scale computers, etc.

The present invention will be described in detail below with reference to examples. However, these examples are merely to illustrate the present invention, and the present invention is not limited by these examples.

### EXAMPLES 1 TO 6 AND COMPARATIVE EXAMPLES 1 TO 2

1) Preparation of Thermosetting Resin Composition

According to the compositions shown in Table 1 below, polyphenylene ether was dissolved in toluene, and then mixed with a cross-linkable curing agent and a flame retardant and stirred for 2 hours. Before adding an inorganic filler and an organic filler to the resin composition, these fillers were stirred in a toluene or MEK solvent and then homogenized with a homogenizer to minimize agglomeration. The organic filler and inorganic filler whose dispersibility was maximized using the homogenizer were added to the resin composition and stirred for 2 hours, and an initiator was added thereto, followed by stirring for 1 hour, thereby preparing a resin composition. In Table 1 below, the amounts of the components of each composition are in units of parts by weight.

2) Production of Laminate Sheet

The resin composition prepared as described above was impregnated into glass fiber, and then dried at 160° C. for 3 to 10 minutes, thereby producing a prepreg. One ply of the prepreg was laminated, and then pressed, thereby producing a laminate sheet having a thickness of 0.1 mm.

TABLE 1

| | | | | | | | | | | Comparative | |
|---|---|---|---|---|---|---|---|---|---|---|---|
| | Examples | | | | | | | | | Examples | |
| | 1 | 2 | 3 | 4 | 5 | 6 | 7 | 8 | 9 | 1 | 2 |
| Allylate | 38 | 35 | 35 | 35 | 34 | 32 | 38 | 32 | 28 | 43 | |
| PPE | | | | | | | | | | | |
| DCPD | | | | | | | | | | | 32 |
| epoxy | | | | | | | | | | | |
| TAIC | 15 | 14 | 14 | 14 | 13 | 13 | 15 | 13 | 9 | 17 | |
| Novolac | | | | | | | | | | | 14 |
| curing | | | | | | | | | | | |
| agent | | | | | | | | | | | |
| Flame | 9 | 8 | 8 | 8 | 8 | 7 | 9 | 7 | 5 | 10 | 10 |
| retardant | | | | | | | | | | | |
| Initiator | 1 | 1 | 1 | 1 | 1 | 1 | 1 | 1 | 1 | 1 | |
| Inorganic | 24 | 24 | 24 | 24 | 22 | 21 | — | — | — | 29 | 22 |
| filler | | | | | | | | | | | |
| PTFE | 13 | 18 | — | — | 22 | 26 | 37 | 47 | 57 | — | 22 |
| filler 1 | | | | | | | | | | | |
| PTFE | — | — | 18 | — | — | — | — | — | — | — | |
| filler 2 | | | | | | | | | | | |
| PTFE | — | — | — | 18 | — | — | — | — | — | — | |
| filler 3 | | | | | | | | | | | |
| Sum | 100 | 100 | 100 | 100 | 100 | 100 | 100 | 100 | 100 | 100 | 100 |

(Notes)
1) Allylate PPE: MX-9000 (number-average molecular weight: 2000 to 3000)
2) TAIC (NIPPON KASEI CHEMICAL)
3) Flame retardant: Saytex8010 (Albemarle Asano Corporation)
4) Initiator: Perbutyl P (NOF Corporation)
5) Inorganic filler: SC-5200SQ (Admatechs)
6) Polytetrafluoroethylene filler 1: MP1200 (Dupont)
7) Polytetrafluoroethylene filler 2: MP1100 (Dupont)
8) Polytetrafluoroethylene filler 3: L-2 (DAIKIN)
9) DCPD epoxy: XD-1000 (Nippon Kayaku)
10) Novolac curing agent: KC-2070 (Kangnam Chemical).

### TEST EXAMPLE 1

### Evaluation of Physical Properties of Laminate Sheets

The physical properties of each of the laminate sheets produced in Examples 1 to 6 and Comparative Examples 1 and 2 were evaluated in the following manner, and the results are shown in Table 2 below.

1) Measurement of Glass Transition Temperature (Tg)

Glass transition temperature (Tg) was measured using DMA (Dynamic Mechanical Analysis) TA Instruments Q800 in accordance with IPC-TM-650-2. 4. 24. 4 (DMA Method).

2) Heat Resistance

Heat resistance was evaluated by floating the laminate sheet at solder 288° C. in accordance with the IPC-TM-650 2.4.13 evaluation standard and measuring the time point when separation occurred between the dielectric layer and the copper foil or between the dielectric layers.

3) Evaluation of T-288

The time to delamination was measured using TMA (Thermo Mechanical Analysis) TA Instruments 2940 in accordance with IPC TM-650 2. 4. 24. 1 (T-288 Method).

4) TGA Td (5% Loss)

A change in 5% loss weight was measured using TGA (Thermo Gravimetric Analysis), TA Instruments Q500 in accordance with IPC-TM-650-2. 4. 24. 6 (TGA Method).

5) Dielectric Constant and Dielectric Loss

In accordance with the IPC TM 650 2.5.5.9 evaluation standards, the laminate sheet was immersed in a copper etching solution to remove the copper foil layer, and the dielectric constant and dielectric loss at a frequency of 1 GHz were measured using a dielectric constant measurement device (RF Impedance/Material Analyzer; Agilent).

6) Flame Retardancy

The laminate sheet was immersed in a copper etching solution to remove the copper foil layer, and a sample having a length of 127 mm and a width of 12.7 mm was prepared therefrom, and then flame retardancy was evaluated according to the UL94 test method (V method).

7) Copper Foil Adhesion (Peel Strength, P/S)

Copper foil adhesion was evaluated in accordance with the IPC-TM-650 2.4.8 evaluation standards by lifting the copper foil layer of the laminate sheet in the 90° direction and measuring the time point when the copper foil layer was peeled off.

TABLE 2

| | | | | | | | | | | Comparative | |
|---|---|---|---|---|---|---|---|---|---|---|---|
| Physical | Examples | | | | | | | | | Examples | |
| properties | 1 | 2 | 3 | 4 | 5 | 6 | 7 | 8 | 9 | 1 | 2 |
| DMA Tg | 221 | 226 | 229 | 233 | 238 | 242 | 223 | 231 | 215 | 210 | 216 |
| (° C.) | | | | | | | | | | | |
| Solder | >10 | >10 | >10 | >10 | >10 | >10 | >10 | >10 | >10 | >10 | >10 |
| Floating | min | min | min | min | min | min | min | min | min | min | min |
| (@288° C.) | | | | | | | | | | | |
| T-288 | >30 | >30 | >30 | >30 | >30 | >30 | >30 | >30 | >30 | >30 | >30 |
| | min | min | min | min | min | min | min | min | min | min | min |
| TGA Td | 410 | 420 | 425 | 426 | 430 | 432 | 419 | 424 | 418 | 406 | 369 |
| (5% loss) | | | | | | | | | | | |
| Dielectric | 3.70 | 3.65 | 3.65 | 3.75 | 3.55 | 3.55 | 3.57 | 3.47 | 3.38 | 3.75 | 4.0 |
| constant | | | | | | | | | | | |
| (Dk @1 GHz) | | | | | | | | | | | |
| Dielectric | 0.0024 | 0.0020 | 0.0021 | 0.0023 | 0.0018 | 0.0018 | 0.0018 | 0.0015 | 0.0012 | 0.0026 | 0.013 |
| loss | | | | | | | | | | | |
| (Df @1 GHz) | | | | | | | | | | | |
| Flame | V-0 | V-0 | V-0 | V-0 | V-0 | V-0 | V-0 | V-0 | V-0 | V-0 | V-0 |
| retardancy | | | | | | | | | | | |
| P/S | 0.7 | 0.6 | 0.6 | 0.6 | 0.5 | 0.4 | 0.5 | 0.4 | 0.4 | 0.8 | 1.0 |
| (kgf/cm) | | | | | | | | | | | |

The test results indicated that the printed circuit board produced using the polytetrafluoroethylene (PTFE) filler of the present invention exhibited excellent characteristics in terms of the dielectric constant and dielectric loss (see Table 2). Specifically, the laminate sheets of Examples 1 to 9 showed excellent glass transition temperature, heat resistance, and low dielectric constant characteristics compared to Comparative Example 2 based on conventional epoxy resin and including the PTEF filler, and also exhibited low dielectric loss (Df) characteristics which were at least 10 times better than those of Comparative Example 2.

In particular, Examples 7 to 9 are the printed circuit boards which are formed using the PTFE filler without using the inorganic filler. It could be seen that these printed circuit boards exhibited significantly better low dielectric loss (Df) characteristics, and other characteristics thereof were comparable to those of Examples 1 to 6 in which the inorganic filler and the PTFE filler were used in combination.

Therefore, it is concluded that according to the present invention, a printed circuit board having excellent dielectric characteristics in an ultrahigh frequency range in future can be produced and will be advantageously used as a constituent material for communication devices and semiconductor devices, which require low dielectric characteristics.

1.-10. (canceled)

11. A thermosetting resin composition comprising:
(a) a polyphenylene ether having two or more unsaturated substituents, selected from the group consisting of vinyl and allyl groups, at both ends of its molecular chain, or an oligomer thereof; and
(b) a polytetrafluoroethylene (PTFE) filler.

12. The thermosetting resin composition of claim 11, wherein a content of the polytetrafluoroethylene filler ranges from 10 to 60 parts by weight based on 100 parts by weight of the composition.

13. The thermosetting resin composition of claim 11, wherein the polytetrafluoroethylene filler has an average particle size of 0.2 to 20 μm and a specific surface area of 1 to 15 m²/g.

14. The thermosetting resin composition of claim 11, wherein the polytetrafluoroethylene filler has an average particle size of 1 to 10 μm and a specific surface area of 1.5 to 12 m²/g.

15. The thermosetting resin composition of claim 11, wherein the polyphenylene ether is represented by Formula 1 below: 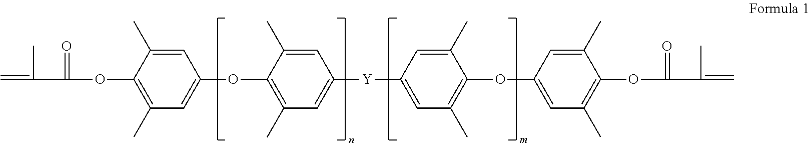
wherein Y is selected from the group consisting of bisphenol A-type resin, bisphenol F-type resin, bisphenol S-type resin, naphthalene-type resin, anthracene resin, biphenyl-type resin, tetramethyl biphenyl-type resin, phenol novolac-type resin, cresol novolac-type resin, bisphenol A novolac-type resin, and bisphenol S novolac-type resin, and m and n are each an integer ranging from 3 to 20.

16. The thermosetting resin composition of claim 11, further comprising one or more selected from the group consisting of (c) an organic filler; (d) a cross-linkable curing agent; and (e) a flame retardant.

17. The thermosetting resin composition of claim 16, wherein the thermosetting resin composition comprises, based on 100 wt % of the thermosetting resin composition:
20 to 45 wt % of the polyphenylene ether or an oligomer thereof;
10 to 60 wt % of the polytetrafluoroethylene filler;
0 to 30 wt % of the inorganic filler;
5 to 20 wt % of the cross-linkable curing agent; and
1 to 15 wt % of the flame retardant.

18. A prepreg comprising:
a fibrous substrate surface-treated with a vinyl group-containing silane coupling agent; and
a resin obtained by impregnating the thermosetting resin composition, set forth in claim 11, into the fibrous substrate.

19. The prepreg of claim 18, wherein a content of the polytetrafluoroethylene filler ranges from 10 to 60 parts by weight based on 100 parts by weight of the composition.

20. The prepreg of claim 18, wherein the polytetrafluoroethylene filler has an average particle size of 0.2 to 20 μm and a specific surface area of 1 to 15 m²/g.

21. The prepreg of claim 18, wherein the polytetrafluoroethylene filler has an average particle size of 1 to 10 μm and a specific surface area of 1.5 to 12 m²/g.

22. The prepreg of claim 18, wherein the polyphenylene ether is represented by Formula 1 below: 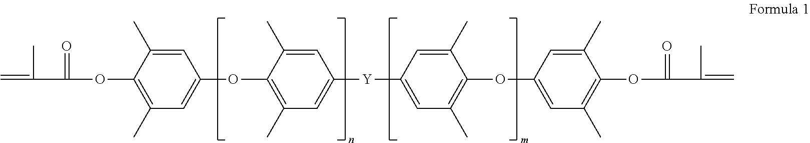
wherein Y is selected from the group consisting of bisphenol A-type resin, bisphenol F-type resin, bisphenol S-type resin, naphthalene-type resin, anthracene resin, biphenyl-type resin, tetramethyl biphenyl-type resin, phenol novolac-type resin, cresol novolac-type resin, bisphenol A novolac-type resin, and bisphenol S novolac-type resin, and m and n are each an integer ranging from 3 to 20.

23. The prepreg of claim 18, further comprising one or more selected from the group consisting of (c) an organic filler; (d) a cross-linkable curing agent; and (e) a flame retardant.

24. The prepreg of claim 23, wherein the thermosetting resin composition comprises, based on 100 wt % of the thermosetting resin composition:
20 to 45 wt % of the polyphenylene ether or an oligomer thereof;
10 to 60 wt % of the polytetrafluoroethylene filler;
0 to 30 wt % of the inorganic filler;
5 to 20 wt % of the cross-linkable curing agent; and
1 to 15 wt % of the flame retardant.

25. A laminate sheet comprising:
a metal foil or a polymer film substrate; and
a resin layer formed on one or both surfaces of the metal foil or polymer film substrate through curing of the thermosetting resin composition set forth in claim 11.

26. The laminate sheet of claim 25, wherein a content of the polytetrafluoroethylene filler ranges from 10 to 60 parts by weight based on 100 parts by weight of the composition.

27. The laminate sheet of claim 25, wherein the polytetrafluoroethylene filler has an average particle size of 0.2 to 20 μm and a specific surface area of 1 to 15 m²/g.

28. The laminate sheet of claim 25, further comprising one or more selected from the group consisting of (c) an organic filler; (d) a cross-linkable curing agent; and (e) a flame retardant.

29. The laminate sheet of claim 25, wherein the thermosetting resin composition comprises, based on 100 wt % of the thermosetting resin composition:
20 to 45 wt % of the polyphenylene ether or an oligomer thereof;
10 to 60 wt % of the polytetrafluoroethylene filler;
0 to 30 wt % of the inorganic filler;
5 to 20 wt % of the cross-linkable curing agent; and
1 to 15 wt % of the flame retardant.

30. A printed circuit board comprising the prepreg of claim 18.
